(19) United States
(12) Patent Application Publication
(10) Pub. No.: US 2025/0198942 A1
(43) Pub. Date: Jun. 19, 2025

(54) Measurements Of Complex Semiconductor Structures Based On Component Measurement Signals

(71) Applicant: KLA Corporation, Milpitas, CA (US)

(72) Inventor: Zhengquan Tan, Cupertino, CA (US)

(21) Appl. No.: 18/972,428

(22) Filed: Dec. 6, 2024

Related U.S. Application Data
(60) Provisional application No. 63/610,426, filed on Dec. 15, 2023.
(60) Provisional application No. 63/548,851, filed on Feb. 2, 2024.

(51) Int. Cl. G01N 21/88; G01N 21/95; H01L 21/66

(52) U.S. Cl. CPC G01N 21/8851; G01N 21/9505; H01L 22/12; G01N 2021/8883; G01N 2201/129

(57) ABSTRACT

Methods and systems for measurements of complex semiconductor structures employing component measurement signals derived from optical, x-ray, or electron based measurements of the structure of interest are described herein. Component measurement signals capture the measurement response of a subset of a number of structural features of the semiconductor structure under measurement. In some embodiments, component measurement signals are employed in the context of a model based regression analysis to estimate values of one or more parameters of interest. In some embodiments, component measurement signals are employed to train machine learning based or library based measurement models. A training set of component measurement signals includes any combination of real signals and synthetically generated signals at present and prior process states from current and historical measurement targets and component targets. In a further aspect, loss functions and exit criteria for different component measurement models of a structure under measurement are defined differently.

### CROSS REFERENCE TO RELATED APPLICATION

The present application for patent claims priority under 35 U.S.C. § 119 from U.S. provisional patent application Ser. No. 63/610,426, filed Dec. 15, 2023, and from U.S. provisional patent application Ser. No. 63/548,851, filed Feb. 2, 2024, the subject matter of each is incorporated herein by reference in its entirety.

### TECHNICAL FIELD

The described embodiments relate to semiconductor metrology systems and methods, and more particularly to methods and systems for improved measurement accuracy.

### BACKGROUND INFORMATION

Semiconductor devices such as logic and memory devices are typically fabricated by a sequence of processing steps applied to a specimen. The various features and multiple structural levels of the semiconductor devices are formed by these processing steps. For example, lithography among others is one semiconductor fabrication process that involves generating a pattern on a semiconductor wafer. Additional examples of semiconductor fabrication processes include, but are not limited to, chemical-mechanical polishing, etch, deposition, and ion implantation. Multiple semiconductor devices may be fabricated on a single semiconductor wafer and then separated into individual semiconductor devices.

Metrology processes are used at various steps during a semiconductor manufacturing process to detect defects on wafers to promote higher yield. A number of x-ray and optical metrology based techniques including scatterometry, ellipsometry, and reflectometry implementations and associated analysis algorithms are commonly used to characterize critical dimensions, film thicknesses, composition and other parameters of nanoscale structures.

As devices (e.g., logic and memory devices) move toward smaller nanometer-scale dimensions, characterization becomes more difficult. Devices incorporating complex three-dimensional geometry and materials with diverse physical properties contribute to characterization difficulty. For example, modern memory structures are often high-aspect ratio, three-dimensional structures fabricated from opaque materials that make it difficult for optical radiation to penetrate to the bottom layers.

To overcome penetration depth issues, traditional imaging techniques such as TEM, SEM etc., are employed with destructive sample preparation techniques such as focused ion beam (FIB) machining, ion milling, blanket or selective etching, etc. For example, transmission electron microscopes (TEM) achieve high resolution levels and are able to probe arbitrary depths, but TEM requires destructive sectioning of the specimen. Several iterations of material removal and measurement generally provide the information required to measure the critical metrology parameters throughout a three dimensional structure. But, these techniques require sample destruction and lengthy process times. The complexity and time to complete these types of measurements introduces large inaccuracies due to drift of etching and metrology steps. In addition, these techniques require numerous iterations which introduce registration errors.

Optical based metrology systems and transmission based X-ray scatterometry systems offer the potential for high-throughput, non-destructive measurement of many advanced targets (e.g., complex 3D structures, structures smaller than 10 nm, structures employing opaque materials) and measurement applications (e.g., line edge roughness and line width roughness measurements).

Traditional optical and X-Ray scatterometry based measurement techniques employ indirect methods of measuring physical properties of a specimen under measurement. In some examples, a physics-based measurement model is created that attempts to predict raw measurement signals based on assumed values of one or more model parameters. The measurement model includes parameters associated with the metrology tool itself, e.g., system parameters and parameters associated with the specimen under measurement. When solving for parameters of interest, some specimen parameters are treated as fixed valued and other specimen parameters of interest are floated, i.e., resolved based on the raw measurement signals.

System parameters are parameters used to characterize the metrology tool. Exemplary system parameters include angle of incidence (AOI), azimuth angle, beam divergence, etc. Specimen parameters are parameters used to characterize the specimen (e.g., material and geometric parameters characterizing the structure(s) under measurement). For a thin film specimen, exemplary specimen parameters include refractive index, dielectric function tensor, nominal layer thickness of all layers, layer sequence, etc. For a CD specimen, exemplary specimen parameters include geometric parameter values associated with different layers, refractive indices associated with different layers, etc. For measurement purposes, the system parameters and many of the specimen parameters are treated as known, fixed valued parameters. However, the values of one or more of the specimen parameters are treated as unknown, floating parameters of interest.

In some examples, the values of the floating parameters of interest are resolved by an iterative process (e.g., regression) that produces the best fit between theoretical predictions and experimental data. The values of the unknown, floating parameters of interest are varied and the model output values are calculated and compared to the raw measurement data in an iterative manner until a set of specimen parameter values are determined that results in a sufficiently close match between the model output values and the experimentally measured values. In some other examples, the floating parameters are resolved by a search through a library of pre-computed solutions to find the closest match.

The indirect approach to estimating values of parameters of interest is challenging to implement due to the complexity of the measurement model required to adequately represent light scattered from a complex semiconductor structure. The measurement model must properly model both the device under measurement and the measurement system to adequately model the physical interaction between the two, i.e., the light scattered from the device under measurement. Lack of measurement sensitivity and parameter correlation limit measurement performance of optical and x-ray based metrology systems.

Optical metrology tools utilizing infrared to visible light can penetrate many layers of translucent materials. Longer wavelengths penetrate deeply into high aspect ratio structures, but measurement sensitivity to small anomalies is limited. In addition, the increasing number of parameters required to characterize complex structures, leads to increasing parameter correlation. As a result, the parameters characterizing the target often cannot be reliably decoupled with available measurement models.

In some examples, optical critical dimension (CD) metrology for etch and lithography applications involve physical measurements of single or multiple targets. However, single target measurements often lack sensitivity or do not provide enough signal information to resolve parameters of interest characterizing complex structures. Multiple target measurements require multiple, physical targets on the device. However, in practice, there is not enough device volume available for large numbers of targets. In addition, in most situations, the required targets are not compatible with the processes employed to manufacture the device. For example, film measurements often require multiple targets that are not compatible with the deposition process.

In some examples, dimensions of parameters of interest measured in a prior process step are employed to break parameter correlations during measurements analyses performed at a subsequent step of the semiconductor process flow. This is commonly referred to as a data feed forward (DFF) technique. However, DFF techniques are limited to certain process steps and require additional measurements at different steps in the process flow that cause undesirable delays in the semiconductor fabrication process flow.

In some examples, raw measurement signals, e.g., measured spectra, collected in a prior process step are employed to enhance measurement performance at a subsequent step of the semiconductor process flow. This is commonly referred to as a spectra feed forward (SFF) technique. However, SFF techniques are limited to certain process steps and very often SFF data is not available for process steps that suffer from a lack of accuracy and robustness.

Many modern memory devices include an array of complex memory structures stacked on top of one another. Unfortunately, for many modern semiconductor devices, scattering images captured at the detector of a transmission based scatterometry tool include overlapping scattered signals. The overlapping scattered signals arise from different structural elements of the complex device under measurement, each characterized by different parameters of interest. As a result, regression on the scattering images is prone to correlation among parameters resulting in higher root mean squared errors of the estimated values of the parameters of interest characterizing the measured array of memory structures. Examples of metrology applications that suffer from overlapping scattered signals include structures with both holes and trenches, multiple layers of holes, tungsten recess and tungsten void in NAND flash memory devices, etc.

X-ray scatterometry based measurements of patterned structures are currently limited due in part to long move, acquire, and measure (MAM) times, lengthy measurement recipe development efforts, and lack of measurement recipe robustness in the face of process changes. Library based solution suffer similar challenges. Machine learning based measurement models have traditionally suffered from robustness issues and lengthy model training efforts. Traditional machine learning based measurement models rely on accurate physical measurement models to generate sufficiently accurate training data. Thus, the lack of sufficiently accurate physical measurement models limits machine learning based measurement model approaches.

In summary, the computational burden and development time required to generate an accurate measurement model for optical and x-ray based based measurements of complex semiconductor structures is a significant barrier to high throughput metrology of modern semiconductor devices.

To further improve device performance, the semiconductor industry continues to focus on vertical integration, rather than lateral scaling. Thus, accurate measurement of complex, fully three dimensional structures is crucial to ensure viability and continued scaling improvements. Future metrology applications present challenges for metrology due to increasingly small resolution requirements, multi-parameter correlation, increasingly complex geometric structures including high aspect ratio structures, and increasing use of opaque materials. Thus, methods and systems for improved optical and x-ray based measurements are desired.

### SUMMARY

Methods and systems for measurements of complex semiconductor structures employing component measurement signals derived from optical, x-ray, or electron based measurements of the structure of interest are described herein. Component measurement signals include measurement signals indicative of the measurement response of a subset of a number of structural features of the semiconductor structure under measurement.

In some embodiments, component measurement signals are employed in the context of a model based regression analysis to estimate values of one or more parameters of interest characterizing a structure under measurement. In some examples, model fitting to component measurement signals reduces computational effort to arrive at a solution and improves measurement robustness. In these examples, a set of component measurement signals is extracted from a set of measurement signals captured from the structure under measurement. Each set of component measurement signals is associated with the measurement response from one or more structural features of the structure under measurement. A trained measurement model is fit to the set of extracted component measurement signals to estimate the value of the parameter of interest.

In some embodiments, component measurement signals are employed to train machine learning based or library based measurement models. In some examples, the resulting measurement models reduce computational effort, increase measurement accuracy, and increase model stability.

In some of these embodiments, a component based measurement model is trained based at least in part on a training set of component measurement signals and corresponding Design of Experiment (DOE) values of the parameter of interest. The training set of component measurement signals is indicative of the measurement response of a subset of a number of structural features of the semiconductor structure under measurement.

In some examples, the training set of component measurement signals includes DOE sets of extracted component measurement signals and corresponding, known values of associated parameters of interest.

In some examples, the training set of component measurement signals includes synthetic component measurement signals generated by a component measurement model evaluated at a range of corresponding values of the parameters of interest and a range of values of one or more measurement system parameters, e.g., angle of incidence, azimuth angle, etc.

In some embodiments, the component models employed to generate synthetic component measurement signals include one or more structural features present in the semiconductor structure under measurement. However, in some embodiments, the component models employed to generate synthetic component measurement signals include one or more instances of structural features that are different from the structural features present in the semiconductor structure under measurement. In some embodiments, these differences are introduced to enhance measurement sensitivity and break correlations between parameters of interest in a trained machine learning based measurement model or a library based measurement model.

In some examples, the training set of component measurement signals includes component measurement signals generated by a measurement of the semiconductor structure at a prior process state. In some of these examples, a subset of the plurality of structural features of the semiconductor structure of interest is present at the prior process state. In this manner, the component measurement signals are actual measurement signals, rather than synthetically generated measurement signals.

In some examples, the training set of component measurement signals includes historical component measurement signals generated by a measurement of a historical version of the component structure by the metrology system. In general, a historical version of a component structure differs from the present version of the component structure in a design revision, a process recipe, or both.

In general, the training data set including the training set of measurement signals and corresponding values of one or more Design of Experiments (DOE) parameters of interest includes any combination of real signals and synthetically generated signals at present and prior process states from current and historical measurement targets and component targets.

In a further aspect, the loss functions and exit criteria for different machine learning component measurement models are defined differently. In this manner, the loss function and exit criteria may be optimized for each individual parameter of interest or group of parameters of interest.

In another aspect, a machine learning based component measurement model is employed to estimate values of one or more parameters of interest based on sets of component measurement signals extracted from measurement signals of a structure under measurement.

In a further aspect, values of one or more parameters of interest estimated by a machine learning based component measurement model from a set of measurement signals are employed as seed values in a regression based fitting of another measurement model to estimate refined values of the one or more parameters of interest.

In general, component measurement functionality as described herein may be implemented on any number of different metrology systems, including, but not limited to, various X-ray based measurement modalities, such as X-ray scatterometry, X-ray reflectometry, X-ray diffraction, X-ray fluorescence, etc., various optically based measurement modalities, such as spectroscopic reflectometry, scatterometry, and ellipsometry, image based reflectometry, etc., and various electron beam based measurement modalities, such as model based electron beam metrology.

The foregoing is a summary and thus contains, by necessity, simplifications, generalizations and omissions of detail; consequently, those skilled in the art will appreciate that the summary is illustrative only and is not limiting in any way. Other aspects, inventive features, and advantages of the devices and/or processes described herein will become apparent in the non-limiting detailed description set forth herein.

### BRIEF DESCRIPTION OF THE DRAWINGS

FIG. 1 is a diagram illustrative of a transmission based, X-Ray metrology system 100 configured to perform component based measurements of semiconductor structures in accordance with the methods described herein.

FIG. 2 is a diagram illustrative of an embodiment of a signal component extraction engine configured to extract component measurement signals associated with different structural features of a measured structure.

FIG. 3 is a diagram illustrative of an embodiment of a regression based component measurement engine 180 configured to fit a trained component based measurement model to sets of extracted component measurement signals to estimate the value of one or more parameters of interest characterizing a measured structure.

FIG. 4 is a diagram illustrative of an embodiment of a machine learning, component measurement engine 170 configured to estimate values of one or more parameters of interest characterizing one or more structural features of a structure under measurement based on component measurement signals and measurement signals associated with the structure under measurement.

FIG. 5 is a simplified diagram illustrative of an embodiment of a component measurement model training engine 160 configured to train a component based measurement model.

FIG. 6 is a diagram illustrative of a measured structure 200 including both trench features 201A-D and hole features 202A-C.

FIG. 7A is a diagram of a hole component structure 203 of measured structure 200 including hole features 202A-C.

FIG. 7B is a diagram of a trench component structure 204 of measured structure 200 including trench features 201A-D.

FIG. 8 is an image 205 illustrative of the measurement response of hole component structure 203 depicted in FIG. 7A.

FIG. 9 is a plot 206 illustrative of the measured pixel intensity along the X-axis depicted in FIG. 8.

FIG. 10 is a plot 209 illustrative of the measured pixel intensity along the Y-axis depicted in FIG. 8.

FIG. 11 is an image 214 illustrative of the measurement response of trench component structure 204 depicted in FIG. 7B.

FIG. 12 is a plot 215 of the measured pixel intensity along the Y-axis depicted in FIG. 11.

FIG. 13 is a diagram illustrative of a Gate All Around (GAA) etch structure 216 as an exemplary structure of interest to be measured by a metrology system as described herein.

FIG. 14A is a diagram illustrative of a component structure 217 including a subset of the structural features of GAA etch structure 216 depicted in FIG. 13.

FIG. 14B is a diagram illustrative of a component structure 218 including a different subset of the structural features of GAA etch structure 216 depicted in FIG. 13.

FIG. 14C is a diagram illustrative of a component structure 219 including the same subset of structural features of GAA etch structure 216 included in component structure 218 depicted in FIG. 14B.

FIG. 14D is a diagram illustrative of a component structure 220 including two instances of a subset of structural features of GAA etch structure 216 depicted in FIG. 13.

FIG. 14E is a diagram illustrative of a component structure 221 including two instances of a subset of structural features of GAA etch structure 216 depicted in FIG. 13.

FIG. 14F is a diagram illustrative of a component structure 222 including two instances of structural features of GAA etch structure 216 and an additional structural feature 223.

FIG. 15 is a diagram illustrative of a FINFET or GAA Litho CD structure 225 as another exemplary structure of interest to be measured by a metrology system as described herein.

FIG. 16A is a diagram illustrative of a component structure 226 including a variation of the structural features of structure 225.

FIG. 16B is a diagram illustrative of a component structure 227 including another variation of the structural features of structure 225.

FIG. 16C is a diagram illustrative of a component structure 228 including another variation of the structural features of structure 225.

FIG. 17 is a diagram illustrative of a Silicon Germanium/Silicon superlattice structure 230 as another exemplary structure of interest to be measured by a metrology system as described herein.

FIG. 18A is a diagram illustrative of a component structure 233 including a variation of the structural features of structure 230.

FIG. 18B is a diagram illustrative of another component structure 234 including a variation of the structural features of structure 230.

FIG. 18C is a diagram illustrative of a component structure 235 including another variation of the structural features of structure 230.

FIG. 18D is a diagram illustrative of a component structure 237 including another variation of the structural features of structure 230.

FIG. 19 is a diagram illustrative of a 3D NAND memory structure 240 as another exemplary structure of interest to be measured by a metrology system as described herein.

FIG. 20A is a diagram illustrative of a component structure 244 including a variation of the structural features of structure 240.

FIG. 20B is a diagram illustrative of a component structure 245 including another variation of the structural features of structure 240.

FIG. 21 depicts a flowchart illustrative of an exemplary method 300 of performing component based measurements of semiconductor structures as described herein.

### DETAILED DESCRIPTION

Reference will now be made in detail to background examples and some embodiments of the invention, examples of which are illustrated in the accompanying drawings.

Methods and systems for measurements of complex semiconductor structures employing component measurement signals derived from optical, x-ray, or electron based measurements of the structure of interest are described herein. Component measurement signals include measurement signals indicative of the measurement response of a subset of a number of structural features of the semiconductor structure under measurement.

The methods and systems described herein are particularly applicable to measurements of semiconductor structures having low measurement signal sensitivity, high parameter correlation, or both. Furthermore, the semiconductor structures are typically characterized by a relatively large number of parameters of interest. Improved training data sets based in part on component measurement signals enable reduced measurement recipe development time, a.k.a., time to solution (TTS), increased measurement accuracy, increased measurement robustness to process variations, reduced measurement run time, and reduced signal acquisition time for optical CD and film measurements, x-ray scatterometry based measurements, etc.

In some embodiments, component measurement signals are employed in the context of a model based regression analysis to estimate values of one or more parameters of interest characterizing a structure under measurement. In some examples, model fitting to component measurement signals reduces computational effort to arrive at a solution and improves measurement robustness.

In some embodiments, component measurement signals are employed to train machine learning based or library based measurement models. In some examples, the resulting measurement models reduce computational effort, increase measurement accuracy, and increase model stability.

Component based measurement models reduce runtime compared to traditional measurement models. This enables significantly reduced Move-Acquire-Move (MAM) times. In some examples, component measurement models enable measurement recipes requiring fewer different measurements. Typically, measurement signals are collected at a number of different values of one or more measurement system parameters, e.g., angles of incidence, azimuth angle, etc., in accordance with a measurement recipe. Values of one or more parameters of interest are determined based on the collected measurement signals. It follows that measurement time decreases as the number of measurements required by a specific measurement recipe decreases.

The methods and systems described herein enable non-destructive metrology and process monitoring and control of the semiconductor fabrication process for complex devices, including, but not limited to, 3D NAND, conventional DRAM, 3D DRAM, 3D FLASH, and future devices with complex patterning and deep structure etch. Moreover, the methods and systems described herein enable effective measurements of more process steps during measurement recipe development and production.

More specifically, the methods and systems described herein benefit measurement applications including, but not limited to, CD and film metrology of Logic FinFET devices, GAA lithography and Etch patterning processes, GAA SiGe/Si superlattice structures, High-K metal gate structures employed to tune threshold voltage, DRAM etch, capacitance measurements, and High-K metal gate structures in peripheral circuits.

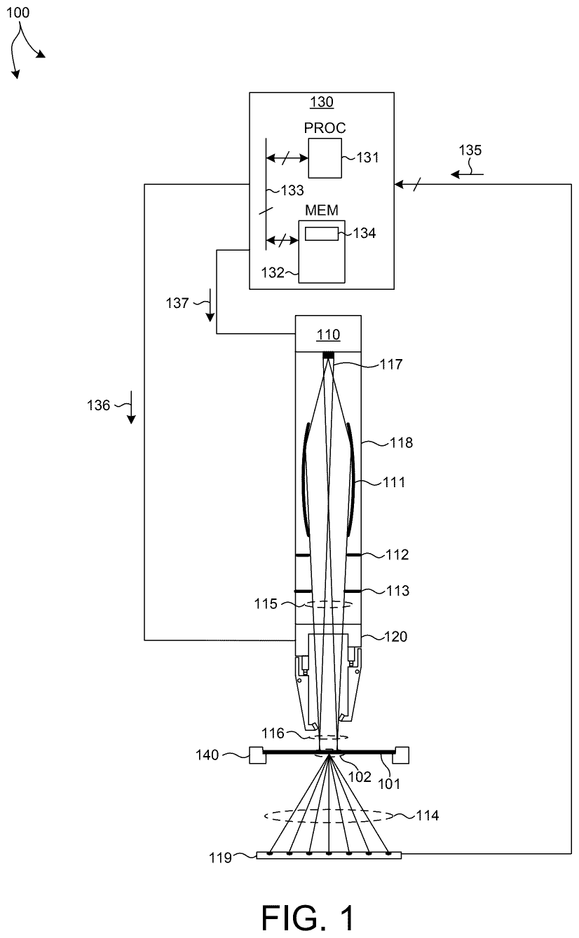

FIG. 1 illustrates an embodiment of a Transmission, Small-Angle X-Ray Scatterometry (T-SAXS) metrology tool 100 for measuring characteristics of a specimen in accordance with the exemplary methods presented herein. As shown in FIG. 1, the system 100 may be used to perform T-SAXS measurements over an inspection area 102 of a specimen 101 illuminated by an illumination beam spot.

In the depicted embodiment, metrology tool 100 includes an x-ray illumination source 110 configured to generate x-ray radiation suitable for T-SAXS measurements. In some embodiments, the x-ray illumination source 110 is configured to generate wavelengths between 0.01 nanometers and 1 nanometer. In general, any suitable high-brightness x-ray illumination source capable of generating high brightness x-rays at flux levels sufficient to enable high-throughput, inline metrology may be contemplated to supply x-ray illumination for T-SAXS measurements. In some embodiments, an x-ray source includes a tunable monochromator that enables the x-ray source to deliver x-ray radiation at different, selectable wavelengths. As depicted in FIG. 1, computing system 130 is configured to control the x-ray illumination generated by x-ray illumination source 110 via control signals 137.

In some embodiments, one or more x-ray sources emitting radiation with photon energy greater than 15 keV are employed to ensure that the x-ray source supplies light at wavelengths that allow sufficient transmission through the entire device as well as the wafer substrate. By way of non-limiting example, any of a particle accelerator source, a liquid anode source, a rotating anode source, a stationary, solid anode source, a microfocus source, a microfocus rotating anode source, a plasma based source, and an inverse Compton source may be employed as x-ray illumination source 110. In one example, an inverse Compton source available from Lyncean Technologies, Inc., Palo Alto, California (USA) may be contemplated. Inverse Compton sources have an additional advantage of being able to produce x-rays over a range of photon energies, thereby enabling the x-ray source to deliver x-ray radiation at different, selectable wavelengths.

Exemplary x-ray sources include electron beam sources configured to bombard solid or liquid targets to stimulate x-ray radiation. Methods and systems for generating high brightness, liquid metal x-ray illumination are described in U.S. Pat. No. 7,929,667, issued on Apr. 19, 2011, to KLA-Tencor Corp., the entirety of which is incorporated herein by reference.

X-ray illumination source 110 produces x-ray emission over a source area having finite lateral dimensions (i.e., non-zero dimensions orthogonal to the beam axis. Focusing optics 111 focuses source radiation onto a metrology target located on specimen 101. The finite lateral source dimension results in finite spot size 102 on the target defined by the rays 117 coming from the edges of the source. In some embodiments, focusing optics 111 includes elliptically shaped focusing optical elements.

A beam divergence control slit 112 is located in the beam path between focusing optics 111 and beam shaping slit mechanism 120. Beam divergence control slit 112 limits the divergence of the illumination provided to the specimen under measurement. An additional intermediate slit 113 is located in the beam path between beam divergence control slit 112 and beam shaping slit mechanism 120. Intermediate slit 113 provides additional beam shaping. In general, however, intermediate slit 113 is optional.

Beam shaping slit mechanism 120 is located in the beam path immediately before specimen 101. In one aspect, the slits of beam shaping slit mechanism 120 are located in close proximity to specimen 101 to minimize the enlargement of the incident beam spot size due to beam divergence defined by finite source size. In one example, expansion of the beam spot size due to shadow created by finite source size is approximately one micrometer for a 10 micrometer x-ray source size and a distance of 25 millimeters between the beam shaping slits and specimen 101. As depicted in FIG. 1, computing system 130 is configured to control the size and shape of illumination beam 116 generated by beam shaping slit mechanism 120 via control signals 136.

In some embodiments, beam shaping slit mechanism 120 includes multiple, independently actuated beam shaping slits (i.e., blades). In one embodiment, beam shaping slit mechanism 120 includes four independently actuated beam shaping slits. These four beams shaping slits effectively block a portion of incoming beam 115 and generate an illumination beam 116 having a box shaped illumination cross-section.

In the embodiment depicted in FIG. 1, focusing optics 111, slits 112 and 113, and beam shaping slit mechanism 120 are maintained in a controlled environment (e.g., vacuum) within a flight tube 118.

In general, x-ray optics shape and direct x-ray radiation to specimen 101. In some examples, the x-ray optics include an x-ray monochromator to monochromatize the x-ray beam that is incident on the specimen 101. In some examples, the x-ray optics collimate or focus the x-ray beam onto measurement area 102 of specimen 101 to less than 1 milliradian divergence using multilayer x-ray optics. In these examples, the multilayer x-ray optics function as a beam monochromator, also. In some embodiments, the x-ray optics include one or more x-ray collimating mirrors, x-ray apertures, x-ray beam stops, refractive x-ray optics, diffractive optics such as zone plates, Montel optics, specular x-ray optics such as grazing incidence ellipsoidal mirrors, polycapillary optics such as hollow capillary x-ray waveguides, multilayer optics or systems, or any combination thereof. Further details are described in U.S. Patent Publication No. 2015/0110249, the content of which is incorporated herein by reference it its entirety.

X-ray detector 119 collects x-ray radiation 114 scattered from specimen 101 and generates an output signals 135 indicative of properties of specimen 101 that are sensitive to the incident x-ray radiation in accordance with a T-SAXS measurement modality. In some embodiments, scattered x-rays 114 are collected by x-ray detector 119 while specimen positioning system 140 locates and orients specimen 101 to produce angularly resolved scattered x-rays.

In some embodiments, a T-SAXS system includes one or more photon counting detectors with high dynamic range (e.g., greater than 10⁵). In some embodiments, a single photon counting detector detects the position and number of detected photons.

In some embodiments, the x-ray detector resolves one or more x-ray photon energies and produces signals for each x-ray energy component indicative of properties of the specimen. In some embodiments, the x-ray detector 119 includes any of a CCD array, a microchannel plate, a photodiode array, a microstrip proportional counter, a gas filled proportional counter, a scintillator, or a fluorescent material.

In this manner the X-ray photon interactions within the detector are discriminated by energy in addition to pixel location and number of counts. In some embodiments, the X-ray photon interactions are discriminated by comparing the energy of the X-ray photon interaction with a predetermined upper threshold value and a predetermined lower threshold value. In one embodiment, this information is communicated to computing system 130 via output signals 135 for further processing and storage.

In a further aspect, a transmission based, X-Ray scatterometry system, e.g., TSAXS measurement system 100, is employed to determine properties of a semiconductor structure (e.g., structural parameter values) based on one or more diffraction orders of scattered light. In the embodiment depicted in FIG. 1, computing system 130 is configured as a component based measurement engine configured to implement component measurement functionality as described herein.

As depicted in FIG. 1, metrology tool 100 includes a computing system 130 employed to acquire signals 135 generated by detector 119 and determine properties of a semiconductor structure based at least in part on the acquired signals in accordance with component based measurement techniques described herein. The transmission based measurements described herein are based on penetration of the incident X-Ray illumination radiation through the semiconductor wafer under measurements. As depicted in FIG. 1, the beam of x-ray illumination light 116 is incident on one side of a semiconductor wafer 101 and the light 114 scattered from the measured structures is collected from the opposite side of the semiconductor wafer 101.

In one aspect, a metrology system is configured to estimate a value of a parameter of interest characterizing the structure under measurement based on the detected radiation using a trained measurement model. The measurement model is trained based at least in part on a training set of component measurement signals and corresponding Design of Experiment (DOE) values of the parameter of interest. The training set of component measurement signals is indicative of the measurement response of a subset of a number of structural features of the semiconductor structure under measurement.

In some examples, a value of a parameter of interest is estimated based on a set of component measurement signals extracted from a set of measurement signals captured from the structure under measurement. Each set of component measurement signals is associated with the measurement response from one or more structural features of the structure under measurement. The trained measurement model is fit to the set of extracted component measurement signals to estimate the value of the parameter of interest.

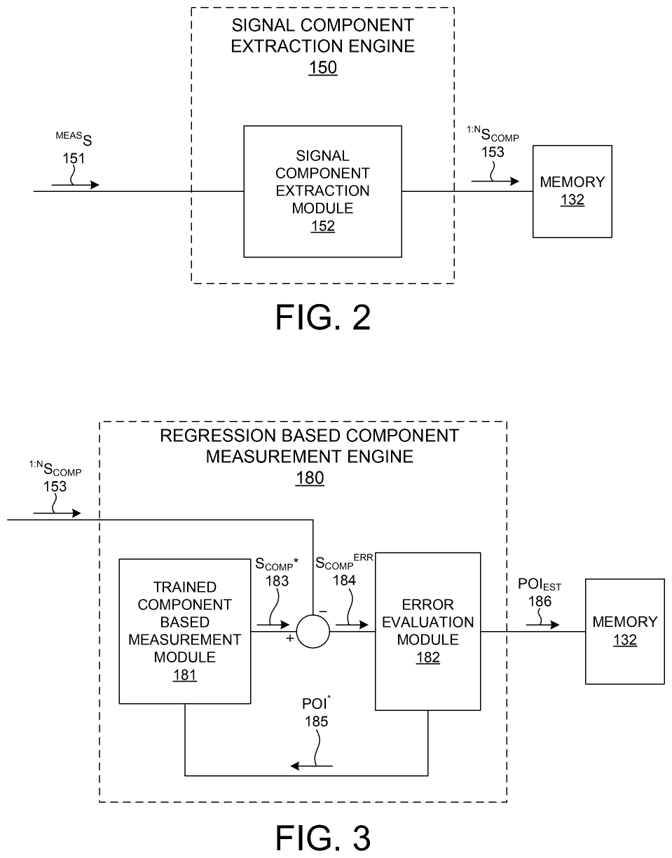

FIG. 2 is a diagram illustrative of a signal component extraction engine 150 implemented by computing system 130 in one embodiment. As depicted in FIG. 2, signal component extraction engine 150 includes signal component extraction module 152. As depicted in FIG. 2, signal component extraction module 152 receives a set of measurement signals, ^{MEAS}S 151 indicative of the scattering response of a structure under measurement including multiple structural features, and generates N sets of component measurement signals, ^{1:N}S_{COMP} 153, each associated with different structural features of the structure under measurement. In general, N is any positive, non-zero integer value. In some embodiments, ^{MEAS}S 151 are scattering response images generated by actual measurements performed by a transmission based X-Ray scatterometry system. In some embodiments, ^{MEAS}S 151 are spectral signals generated by measurements performed by a spectroscopic measurement system. In some embodiments, ^{MEAS}S 171, are contrast images generated by an electron based measurement system.

Signal component extraction module 152 sorts the measured signals, ^{MEAS}S 151, according to each parameter of interest. In some examples, signal extraction module 152 sorts measured signals based on symmetrical patterns or other structural patterns in the detected images. Symmetry includes symmetrical patterns of pixel intensities across the detected images. Patterns of pixel intensities include both bright and dark portions of the detected images, i.e., regions of brightness and darkness present in the detected images. In a further aspect, signal component extraction module 152 associates the sorted patterns with specific structural features characterized by one or more parameters of interest.

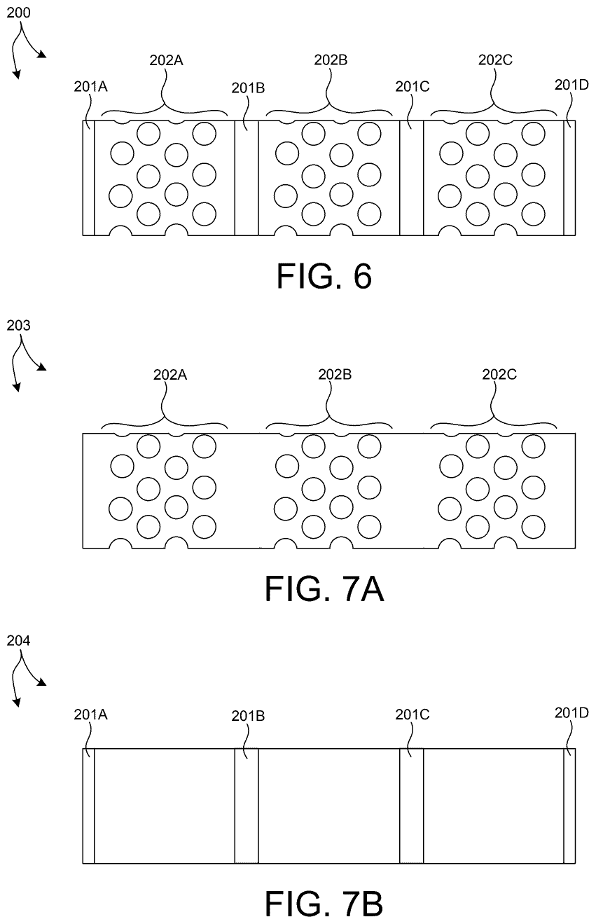

In one example, measured signals are sorted by a symmetrical pattern associated with an array of hole features, and another symmetrical pattern associated with an array of trench features of a structure under measurement. FIG. 6 is a diagram illustrative of a measured structure 200 including both trench features 201A-D and hole features 202A-C.

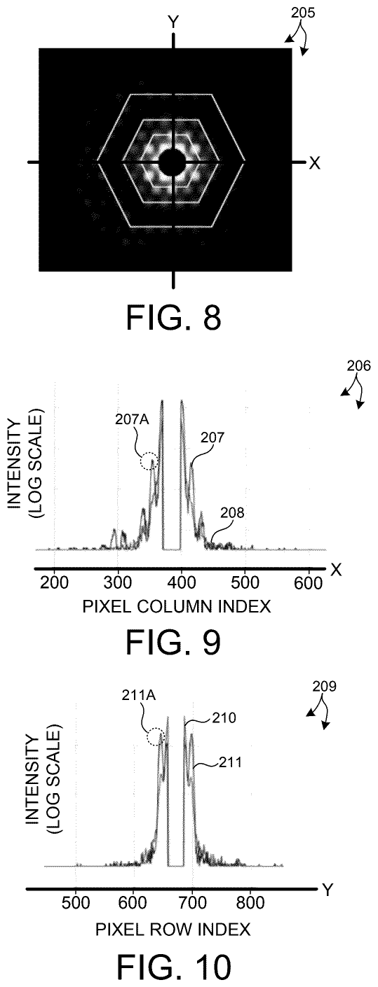

FIG. 7A is a diagram of a hole component structure 203 of measured structure 200 including hole features 202A-C, e.g., channel holes, but not trench features 201A-D. FIG. 8 is a detected image 205 indicative of the measurement response of hole component structure 203 depicted in FIG. 7A. Detected image 205 exhibits concentric hexagonal pixel intensity patterns indicative of the measurement response of hole component structure 203. As depicted in FIG. 8, the detected image is symmetrical about the X-axis and the Y-axis depicted in FIG. 8. FIG. 9 is a plot 206 of the measured pixel intensity along the X-axis depicted in FIG. 8, i.e., across the columns of pixels illustrated in FIG. 8 along the X-axis. FIG. 9 includes plotline 207 associated with a detected image measured at a high-Q (momentum) resolution and plotline 208 associated with a detected image measured at a low-Q resolution. The sets of pixel values illustrated by plotlines 207 and 208 are exemplary sets of component measurement signals, ^{1:N}S_{COMP} 153, each associated with the hole component structure 203 of the structure 200 under measurement.

FIG. 10 is a plot 209 of the measured pixel intensity along the Y-axis depicted in FIG. 8, i.e., across the rows of pixels illustrated in FIG. 8 along the Y-axis. FIG. 10 includes plotline 211 associated with a detected image measured a high-Q resolution and plotline 210 associated with a detected image measured at a low-Q resolution. The sets of pixel values illustrated by plotlines 210 and 211 are also exemplary sets of component measurement signals, ^{1:N}S_{COMP} 153, each associated with the hole component structure 203 of the structure 200 under measurement.

As depicted in FIGS. 9 and 10, the distance between the location of the first order diffraction peak, indicated by reference numeral 207A in FIG. 9 and reference numeral 211A in FIG. 10, and the zero order response is indicative of the critical dimension (CD) of the hole pattern features 202A-C. The greater the distance between the first order peak and the zero order response, the smaller the hole CD, and vice-versa. Thus, the sets of component measurement signals illustrated in FIGS. 9 and 10 are sensitive to and strongly correlated with hole CD.

FIG. 7B is a diagram of a trench component structure 204 of measured structure 200 including trench features 201A-D, but not hole features 202A-C, e.g., wordline tungsten and trenches without channel hole structures.

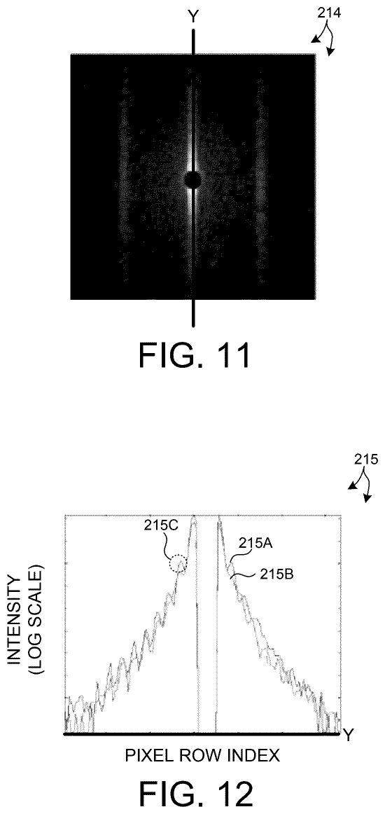

FIG. 11 is a detected image 214 indicative of the measurement response of trench component structure 204 depicted in FIG. 7B. Detected image 214 exhibits pixel intensity patterns that are very different from the pixel intensity patterns associated with hole component structure 203. Detected image 214 exhibits peridiodic, vertically oriented pixel intensity patterns indicative of the measurement response of trench component structure 204. As depicted in FIG. 11, the detected image is symmetrical about the Y-axis depicted in FIG. 11. FIG. 12 is a plot 215 of the measured pixel intensity along the Y-axis depicted in FIG. 11, i.e., across the rows of pixels illustrated in FIG. 11 along the Y-axis. FIG. 12 includes plotline 215A associated with a detected image measured at a high-Q resolution and plotline 215B associated with a detected image measured at a low-Q resolution. The sets of pixel values illustrated by plotlines 215A and 215B are exemplary sets of component measurement signals, ^{1:N}S_{COMP} 153, each associated with the trench component structure 204 of the structure 200 under measurement.

As depicted in FIG. 12, the distance between the location of the first order diffraction peak, indicated by reference numeral 215C in FIG. 12, and the zero order response is indicative of the critical dimension (CD) of the trench pattern features 201A-D depicted in FIG. 7B. The greater the distance between the first order peak and the zero order response, the smaller the trench CD, and vice-versa. Thus, the sets of component measurement signals illustrated in FIG. 12 are sensitive to and strongly correlated with trench CD.

In a further aspect, a component based measurement model is trained based on DOE sets of extracted component measurement signals, ^{DOE}S_{COMP}, and corresponding values of the associated parameters of interest, e.g., hole CD and trench CD. The trained component based measurement model is subsequently employed to estimate values of one or more parameters of interest based on sets of component measurement signals extracted from measurement signals of a structure under measurement.

FIG. 3 is a diagram illustrative of a regression based component measurement engine 180. Regression based component measurement engine 180 fits a trained component based measurement model to sets of extracted component measurement signals to estimate the value of one or more parameters of interest. Regression based component measurement engine 180 includes a trained component based measurement module 181 including a trained component based measurement model and error evaluation module 182. Trained component based measurement module 181 generates estimated component measurement signals, S_{COMP}* 183, based on assumed values of one or more parameters of interest. Regression based component measurement engine 180 determines component measurement error signals, S_{COMP}^{ERR} 184, as a difference between the estimated component measurement signals, S_{COMP}* 183, and component measurement signals, ^{1:N}S_{COMP} 153, extracted from actual measurement signals associated with a structure under measurement. The component measurement error signals, S_{COMP}^{ERR} 184, are communicated to error evaluation module 182. Error evaluation module 182 generates updated values of the parameters of interest, POI* 185, based on the component measurement error signals, S_{COMP}^{ERR} 184. The updated values, POI* 185, are communicated to trained component based measurement module 181. Trained component based measurement module 181 generates estimated component measurement signals, S_{COMP}* 183, based on the updated values of one or more parameters of interest. Regression based component measurement engine 180 iterates until an exit criteria is reached, e.g., component measurement error signals, S_{COMP}^{ERR} 184, fall below predetermined threshold values, a maximum number of iterations in reached, etc. When the exit criteria are reached, the regression based component measurement engine 180 communicates the estimated values of the one or more parameters of interest, POI_{EST} 186, to a memory, e.g., memory 132.

In some embodiments, the trained component based measurement model is a physics based, library based, or machine learning based measurement model structured to generate estimated values of component measurement signals directly.

In some other embodiments, the trained component based measurement model is a physics based, library based, or machine learning based measurement model structured to generate estimated values of measurement signals, which are subsequently processed by signal component extraction engine 150 to generate estimated values of component measurement signals.

In another aspect, a machine learning based component measurement model is employed to estimate values of one or more parameters of interest based on sets of component measurement signals extracted from measurement signals of a structure under measurement.

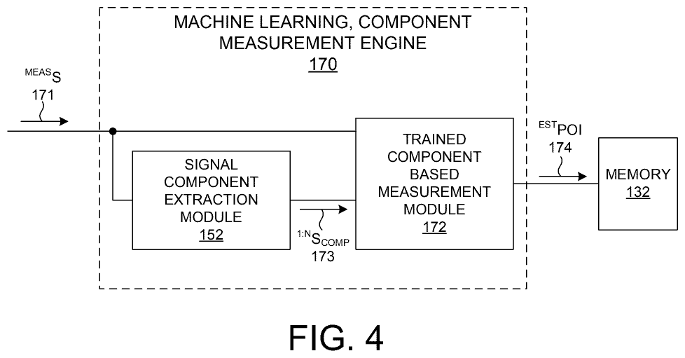

FIG. 4 is a diagram illustrative of a machine learning, component measurement engine 170. Machine learning, component measurement engine 170 includes signal component extraction module 152 and trained component based measurement module 172. As depicted in FIG. 4, machine learning, component measurement engine 170 receives a set of measurement signals, ^{MEAS}S 171, indicative of the response of a structure under measurement, including multiple structural features. In some embodiments, ^{MEAS}S 171, are scattering response images generated by actual measurements performed by a transmission based X-Ray scatterometry system. In some embodiments, ^{MEAS}S 171, are spectral signals generated by actual measurements performed by a spectroscopic measurement system. In some embodiments, ^{MEAS}S 171, are contrast images generated by an electron based measurement system.

As depicted in FIG. 4, ^{MEAS}S 171, are communicated to both trained component based measurement module 172 and signal component extraction module 152. Signal component extraction module 152 receives measurement signals, ^{MEAS}S 171, and generates N sets of component measurement signals, ^{1:N}S_{COMP} 173, each associated with different structural components of the structure under measurement. Component measurement signals, ^{1:N}S_{COMP} 173, are communicated to trained component based measurement module 172. Trained component based measurement module 172 includes at least one trained component based measurement model that estimates values of one or more parameters of interest, ^{EST}POI 174, characterizing one or more structural features of the structure under measurement based on component measurement signals, ^{1:N}S_{COMP} 173, and measurement signals, ^{MEAS}S 171. The estimated values, ^{EST}POI 174, are stored in a memory, e.g., memory 132.

In a further aspect, a machine learning or library based component measurement model is trained based on DOE sets of extracted component measurement signals and corresponding, known values of associated parameters of interest.

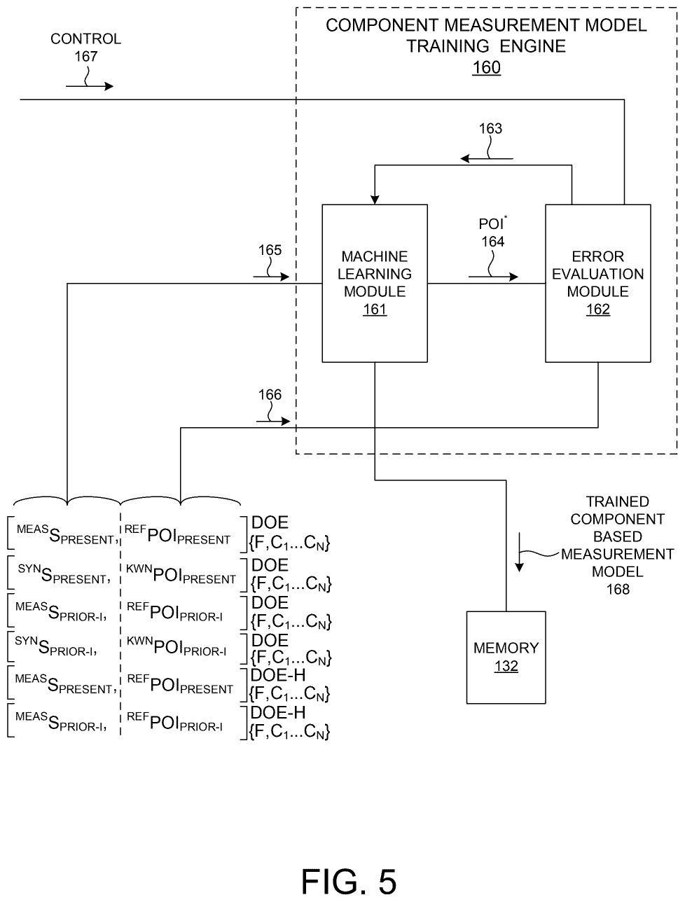

FIG. 5 is a diagram illustrative of a component measurement model training engine 160, including a machine learning module 161 and an error evaluation module 162. Component measurement model training engine 160 receives a training set of measurement signals 165 and corresponding values of one or more Design of Experiments (DOE) parameters of interest 166. Machine learning module 161 includes at least one machine learning based component measurement model under training. In the example depicted in FIG. 5, machine learning module 161 includes a full measurement model, F, and N different component measurement models, C₁ . . . C_{N}, where N is any positive integer value. Full measurement model, F, estimates values of one or more parameters of interest based on a set of measurement signals associated with measurements of the semiconductor structure under measurement. Each different component measurement model estimates values of one or more parameters of interest characterizing structural features of the semiconductor structure under measurement based on a set of component measurement signals extracted measurements of the semiconductor structure.

Machine learning module 161 receives the training set of measurement signals 165 and estimates values of one or more parameters of interest, POI* 164, based on the training set of measurement signals 165 using full measurement model, F, and N different component measurement models, C₁ . . . C_{N}. The estimated values, POI* 164, are communicated to error evaluation module 162. Error evaluation module 162 determines updated values of weighting parameters 163 associated with full measurement model, F, and component measurement models, C₁ . . . C_{N}, based on differences between the model estimated values, POI* 164, and the corresponding DOE POI values 166. The iterative training sequence is repeated until differences between the model estimated values, POI* 164, and the corresponding DOE POI values 166 are minimized. The resulting one or more trained component based measurement models 168 are stored in a memory, e.g., memory 132.

As depicted in FIG. 5, control parameters 167 are communicated to error evaluation module 162 to control the training process. In some examples, control parameters 167 define the loss functions and exit criteria for each different machine learning component measurement model. In some examples, the loss functions and exit criteria for one or more different machine learning component measurement models are defined differently. In this manner, the loss function and exit criteria may be optimized for each individual parameter of interest or group of parameters of interest.

In a further aspect, a machine learning component measurement model training engine includes a weighting module that assigns different weighting values to different sets of training data. The relative weighting of different sets of training data emphasizes training data sets assigned a relatively high weighting and deemphasizes training data sets assigned a relatively low weighting. In this manner, training data sets associated with a higher level of trust in the data or higher correlation to the current version of the structure of interest in the present state are emphasized over training data sets that are less trusted or have lower correlation to the current version of the structure of interest in the present state.

In some examples, the training set of component measurement signals 165 includes DOE component measurement signals, ^{1:N}S_{COMP}^{DOE}, extracted from a DOE set of measurement signals, ^{MEAS}S_{PRESENT}^{DOE}, indicative of a measured response of the structure under measurement by the metrology system. Each of the N sets of DOE component measurement signals corresponds to the N different component measurement models, C₁ . . . C_{N}. The corresponding reference values of the parameters of interest, ^{REF}POI_{PRESENT}^{DOE}, are known values of the parameters of interest measured by a trusted reference metrology system, e.g., a scanning electron microscope, a transmission electron microscope, etc.

In some examples, the training set of component measurement signals 165 includes synthetic component measurement signals generated by a component measurement model evaluated at a range of corresponding values of the parameters of interest and a range of values of one or more measurement system parameters, e.g., angle of incidence, azimuth angle, etc.

Synthetically generated training data enables model training over a broader range of target geometries and measurement system settings without the need to generate additional real targets on the device to be measured. This saves computational effort and measurement time during measurement recipe development and results in measurement models with improved accuracy and robustness.

Synthetically generated training data is simulated using measurement models corresponding to the same measurement tool and technologies employed in the actual measurement of the semiconductor structure of interest, e.g., same measurement technology, same measurement system model, and same physical simulation models.

In the example depicted in FIG. 5, each of the N different component measurement models, C₁ . . . C_{N}, generates sets of synthetic component measurement signals generated over a range of values of the parameters of interest corresponding to each component measurement model and a range of values of one or more measurement system parameters. In addition, the full measurement model, F, generates sets of synthetic measurement signals generated over a range of values of the parameters of interest corresponding to the full measurement model and a range of values of one or more measurement system parameters. ^{SYN}S_{PRESENT}, illustrated in FIG. 5, includes the sets of synthetic measurement signals and synthetic component measurement signals. The corresponding values of the parameters of interest, ^{KWN}POI_{PRESENT} are known values employed to generate the synthetic data sets.

In some embodiments, the component models employed to generate synthetic component measurement signals include one or more structural features present in the semiconductor structure under measurement. However, in some embodiments, the component models employed to generate synthetic component measurement signals include one or more instances of structural features that are different from the structural features present in the semiconductor structure under measurement. In some embodiments, these differences are introduced to enhance measurement sensitivity and break correlations between parameters of interest in a trained machine learning based measurement model or a library based measurement model.

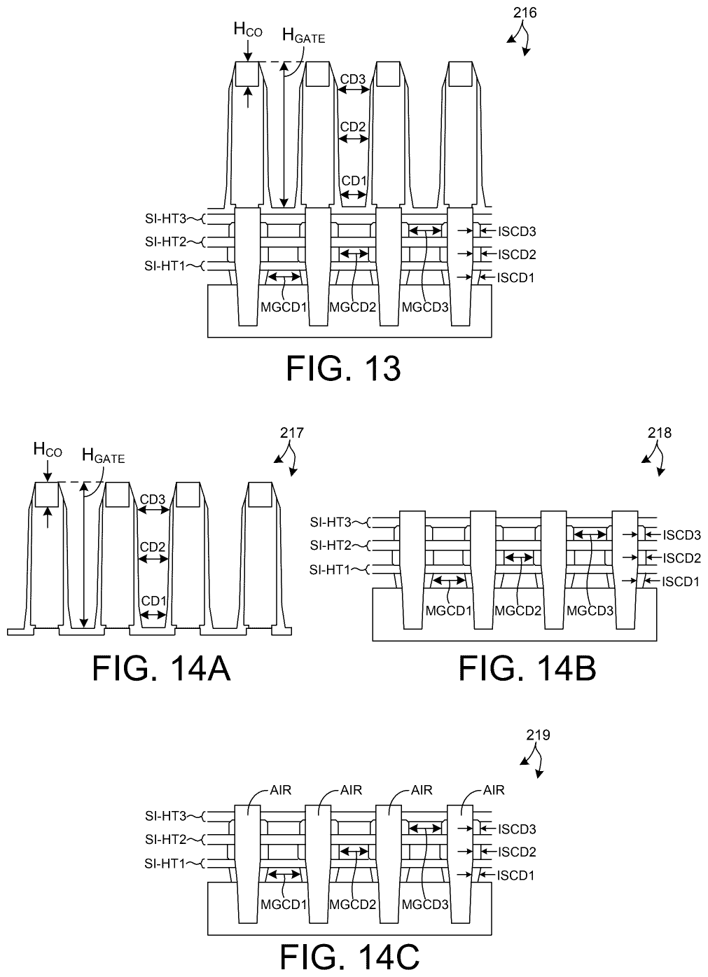

FIG. 13 is a diagram illustrative of a Gate All Around (GAA) etch structure 216. GAA etch structure 216 is the actual structure of interest to be measured by a metrology system as described herein. As depicted in FIG. 13, structure 216 is characterized by a number of parameters of interest, CO height, H_{CO}, gate height, H_{GATE}, gate CD1, gate CD2, gate CD3, inner spacer CD1, inner spacer CD2, inner spacer CD3, metal gate CD1, metal gate CD2, metal gate CD3, silicon spacer HT1, silicon spacer HT2, and silicon spacer HT3.

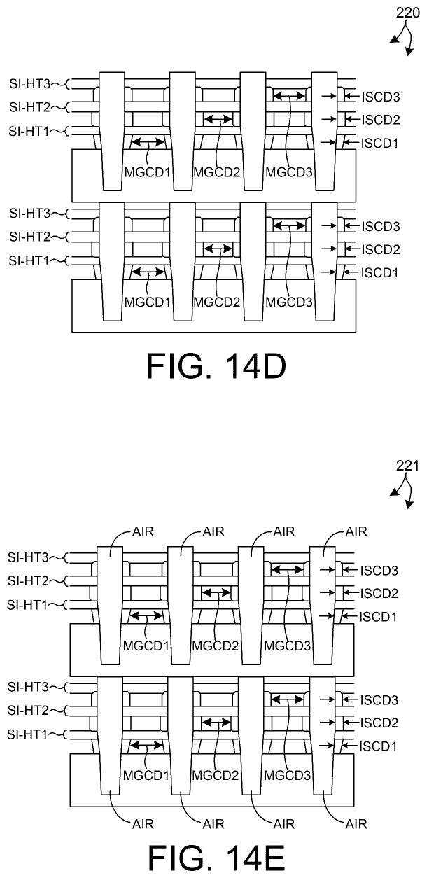

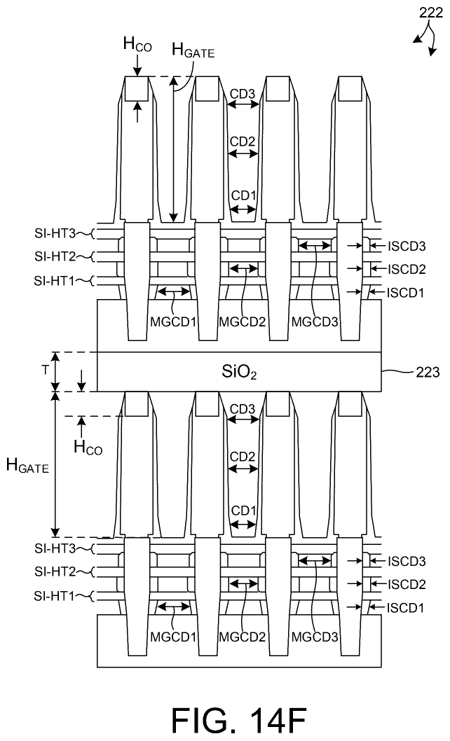

FIG. 14A is a diagram illustrative of a component

structure 217 including a subset of the structural features of GAA etch structure 216. The structural features of GAA etch structure 216 included in component structure 217 include CO height, H_{CO}, gate height, H_{GATE}, gate CD1, gate CD2, and gate CD3. The structural features of component structure 217 are constrained to be identical to GAA etch structure 216 in shape, dimension, and material properties, e.g., composition, dispersion parameter values, etc.

FIG. 14B is a diagram illustrative of a component structure 218 including a different subset of the structural features of GAA etch structure 216. The structural features of GAA etch structure 216 included in component structure 218 include inner spacer CD1, inner spacer CD2, inner spacer CD3, metal gate CD1, metal gate CD2, metal gate CD3, silicon spacer HT1, silicon spacer HT2, and silicon spacer HT3. The structural features of component structure 218 are constrained to be identical to GAA etch structure 216 in shape, dimension, and material properties, e.g., composition, dispersion parameter values, etc.

FIG. 14C is a diagram illustrative of a component structure 219 including the same subset of structural features of GAA etch structure 216 included in component structure 218. However, the structural features of component structure 219 are not constrained to be identical to GAA etch structure 216 in shape, dimension, and material properties. In the example depicted in FIG. 14C, the material characteristics of the epitaxial Silicon Germanium structures of GAA etch structure 216 are replaced by air in component structure 219.

FIG. 14D is a diagram illustrative of a component structure 220 including two instances of a subset of structural features of GAA etch structure 216. More specifically, component structure 220 includes two instances of the subset of structural features included in component structure 218 stacked on top of one another.

FIG. 14E is a diagram illustrative of a component structure 221 including two instances of a subset of structural features of GAA etch structure 216. However, the structural features of component structure 221 are not constrained to be identical to GAA etch structure 216 in shape, dimension, and material properties. More specifically, component structure 221 includes two instances of the subset of structural features included in component structure 219 stacked on top of one another.

FIG. 14F is a diagram illustrative of a component structure 222 including two instances of structural features of GAA etch structure 216 and an additional structural feature 223. More specifically, component structure 222 includes two stacked instances of the structural features included in GAA etch structure 216 separated by a layer 223 of silicon oxide, having a thickness, T.

In some examples, synthetic training data sets, {^{SYN}S_{PRESENT}, ^{KWN}POI_{PRESENT}}, depicted in FIG. 5, include simulated measurement signals associated with measurements of GAA etch structure 216 and component structures 217-221 over a range of values of the parameters of interest and measurement system parameters. In some examples, actual measurement training data sets, {_{MEAS}S_{PRESENT}, ^{REF}POI_{PRESENT}}, include actual measurement signals associated with DOE measurements of GAA etch structure 216 and corresponding trusted values of the parameters of interest over a DOE range of values of the parameters of interest and measurement system parameters.

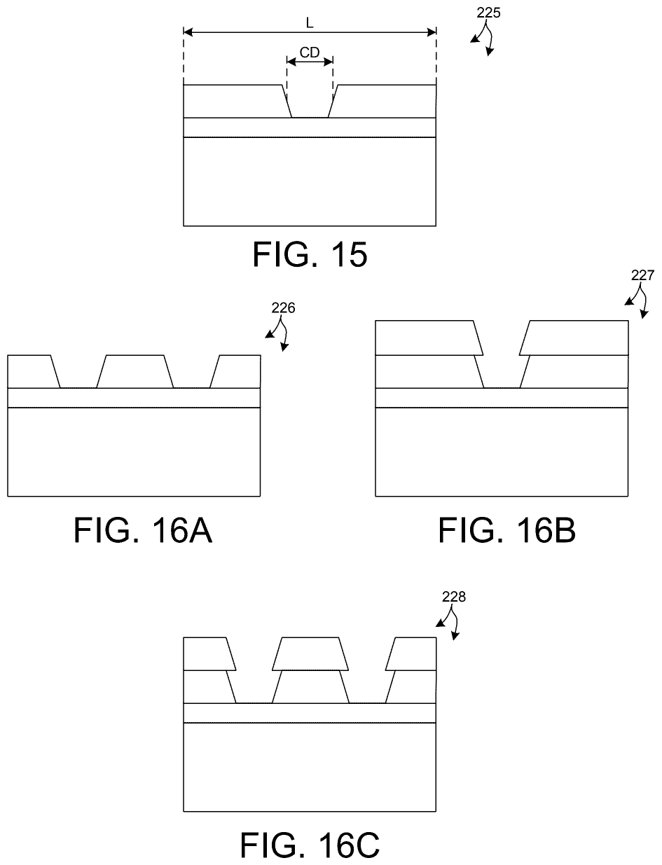

FIG. 15 is a diagram illustrative of a FINFET or GAA Litho CD structure 225. Structure 225 is the actual structure of interest to be measured by a metrology system as described herein. Structure 225 is a high ISO ratio, i.e., the unit cell of the patterned structural feature is significantly larger than the critical dimension characterizing each repeated feature. In the example depicted in FIG. 15, the length, L, of the unit cell of a pattern of hole features is five times the CD of each hole feature. In this example, the ISO ratio of structure 225 is 5:1.

FIG. 16A is a diagram illustrative of a component structure 226 including a variation of the structural features of structure 225. Component structure 226 includes two instances of the hole feature of structure 225 spaced more closely together. In this example, the ISO ratio of structure 226 is 2:1.

FIG. 16B is a diagram illustrative of a component structure 227 including a variation of the structural features of structure 225. Component structure 227 includes two instances of the hole feature of structure 225 stacked on top of one another. In this example, the ISO ratio of structure 227 is 5:1.

FIG. 16C is a diagram illustrative of a component structure 228 including a variation of the structural features of structure 225. Component structure 228 includes two instances of the hole features of structure 226 stacked on top of one another. In this example, the ISO ratio of structure 228 is 2:1.

In some examples, synthetic training data sets, {^{SYN}S_{PRESENT}, ^{KWN}POI_{PRESENT}}, depicted in FIG. 5, include simulated measurement signals associated with measurements of structure 225 and component structures 226-228 over a range of values of the parameters of interest and measurement system parameters. In some examples, actual measurement training data sets, {^{MEAS}S_{PRESENT}, ^{REF}POI_{PRESENT}}, include actual measurement signals associated with DOE measurements of structure 225 and corresponding trusted values of the parameters of interest over a DOE range of values of the parameters of interest and measurement system parameters.

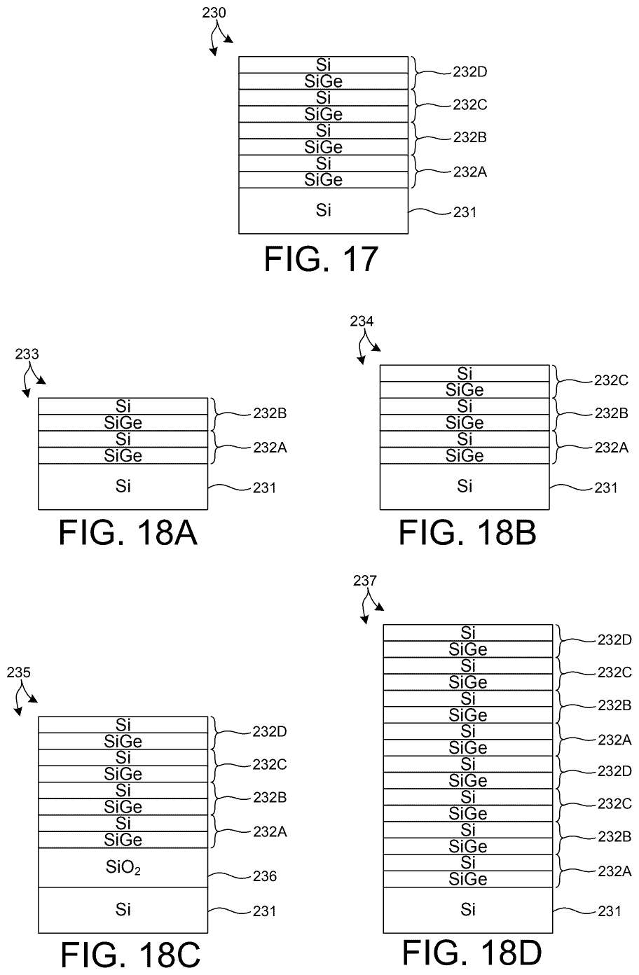

FIG. 17 is a diagram illustrative of a Silicon Germanium/Silicon superlattice structure 230 including a Silicon substrate 231 and four stacked layer sets 232A-D, each including a Silicon Germanium layer and a crystalline Silicon layer. Structure 230 is the actual structure of interest to be measured by a metrology system as described herein. The parameters of interest are the thicknesses of each layer and the percentage of Silicon Germanium in each Silicon Germanium layer.

FIG. 18A is a diagram illustrative of a component structure 233 including a variation of the structural features of structure 230. Component structure 233 includes the Silicon substrate 231 and two stacked layer sets 232A-B.

FIG. 18B is a diagram illustrative of a component structure 234 including a variation of the structural features of structure 230. Component structure 234 includes the Silicon substrate 231 and three stacked layer sets 232A-C.

FIG. 18C is a diagram illustrative of a component structure 235 including a variation of the structural features of structure 230. Component structure 235 includes the Silicon substrate 231, a Silicon Oxide layer 236, and four stacked layer sets 232A-D.

FIG. 18D is a diagram illustrative of a component structure 237 including a variation of the structural features of structure 230. Component structure 237 includes the Silicon substrate 231, and two instances of stacked layer sets 232A-D stacked on top of one another.

In some examples, synthetic training data sets, {^{SYN}S_{PRESENT}, ^{KWN}POI_{PRESENT}}, depicted in FIG. 5, include simulated measurement signals associated with measurements of structure 230 and component structures 233-235 and 237 over a range of values of the parameters of interest and measurement system parameters. In some examples, actual measurement training data sets, {^{MEAS}S_{PRESENT}, ^{REF}POI_{PRESENT}}, include actual measurement signals associated with DOE measurements of structure 230 and corresponding trusted values of the parameters of interest over a DOE range of values of the parameters of interest and measurement system parameters.

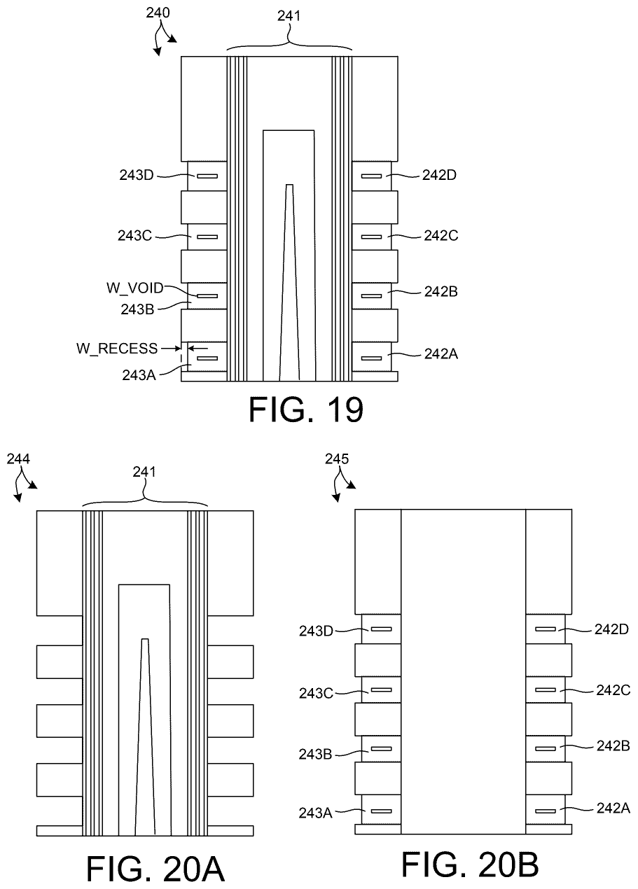

FIG. 19 is a diagram illustrative of a 3D NAND memory structure 240 including recessed tungsten fill features 242A-D and 243A-D and a poly fill features 241. Structure 240 is the actual structure of interest to be measured by a metrology system as described herein. The parameters of interest are the tungsten recess dimensions associated with each recessed tungsten fill feature and tungsten void dimensions associated with each recessed tungsten fill feature.

FIG. 20A is a diagram illustrative of a component structure 244 including a variation of the structural features of structure 240. Component structure 244 includes the structural elements of structure 240 without the tungsten fill features 242A-D and 243A-D.

FIG. 20B is a diagram illustrative of a component structure 245 including a variation of the structural features of structure 240. Component structure 245 includes the structural elements of structure 240 without the poly fill feature 241.

In some examples, synthetic training data sets, {^{SYN}S_{PRESENT}, ^{KWN}POI_{PRESENT}}, depicted in FIG. 5, include simulated measurement signals associated with measurements of structure 240 and component structures 244-245 over a range of values of the parameters of interest and measurement system parameters. In some examples, actual measurement training data sets, {^{MEAS}S_{PRESENT}, ^{REF}POI_{PRESENT}}, include actual measurement signals associated with DOE measurements of structure 240 and corresponding trusted values of the parameters of interest over a DOE range of values of the parameters of interest and measurement system parameters.

In a further aspect, the training set of component measurement signals includes component measurement signals generated by a measurement of the semiconductor structure at a prior process state. In some of these examples, a subset of the plurality of structural features of the semiconductor structure of interest are present at the prior process state. In this manner, the component measurement signals are actual measurement signals, rather than synthetically generated measurement signals.

In some examples, prior state measurement data

are employed to train a present state, component measurement model. This approach takes advantage of the correlation between structural characteristics of measured samples fabricated before and after one or more intervening process steps. In these examples, a present state, component measurement model is trained using training data associated with measurements of a plurality of instances of a current version of a semiconductor structure in a prior state of a semiconductor process flow.

A present state indicates the state of the semiconductor structure after the latest process step applied to the semiconductor structure, and before any subsequent process steps are applied to the semiconductor structure. A prior state indicates the state of the semiconductor structure before the latest process step was applied to the semiconductor structure. Prior state training data is derived from actual or simulated measurement of present or historical instances of the structure of interest fabricated on one or more production wafers in the ith prior state, where i is any non-zero positive integer number bounded by the total number of prior process states before the present process state in the semiconductor fabrication process flow. In some examples, a significant amount of validated measurement data is collected from a semiconductor structure in a prior state. In some of these examples, accurate measurements of one or more parameters of interest in a prior state are relatively easy to obtain compared to a present state.

In some embodiments, a training data set includes actual measurement signals associated with a measurement of each of a plurality of instances of the current version of the semiconductor structure in a prior process state, MEASSPRIOR-I, and corresponding measured values of the parameter of interest associated with a reference measurement of each of the plurality of instances of the current version of the semiconductor structure by a reference metrology system, ^{KWN}POI_{PRIOR-I}.

In some embodiments, a training data set includes assumed values of a parameter of interest characterizing the current version of the semiconductor structure in a prior process state, ^{SYN}POI_{PRIOR-I}, and synthetically generated measurement signals corresponding to each of the assumed values of a parameter of interest, ^{SYN}S_{PRIOR-I}.

In general, the training data set may include actual and synthetically generated measurement signals and corresponding values of one or more parameters of interest associated with the full structure of interest, any combination of the component structures, {C₁ . . . C_{N}}, or both.

In a further aspect, the training set of component measurement signals includes historical component measurement signals generated by a measurement of a historical version of the component structure by the metrology system. In general, a historical version of a component structure differs from the present version of the component structure in a design revision, a process recipe, or both. A version of a semiconductor structure indicates the design version of a semiconductor structure, a process recipe version employed to fabricate the semiconductor structure, or both. A current version of a semiconductor structure is the design revision, process recipe, or both, associated with semiconductor structure for which a present state measurement model is being trained. A historical version of the semiconductor structure is a different design revision, different process recipe, or both, associated with the semiconductor structure. Typically, a historical version of a semiconductor structure is an earlier design revision, earlier process recipe, or both, for which a significant amount of validated measurement data has been collected. In this manner, measurement data associated with historical versions of a semiconductor structure are typically trusted.

In some embodiments, a training data set includes actual measurement signals, {^{MEAS}S_{PRESENT}}^{DOE-H}, associated with a measurement of each of a plurality of instances of a historical version of the semiconductor structure in a present process state and a corresponding measured value of the parameter of interest, {^{REF}POI_{PRESENT}}^{DOE-H}, associated with a reference measurement of each of the plurality of instances of the historical version of the semiconductor structure in the present process state by a reference metrology system.

In some embodiments, a training data set includes actual measurement signals, {^{MEAS}S_{PRIOR-I}}^{DOE-H}, associated with a measurement of each of a plurality of instances of a historical version of the semiconductor structure in a prior process state and a corresponding measured value of the parameter of interest, {^{REF}POI_{PRIOR-I}}^{DOE-H}, associated with a reference measurement of each of the plurality of instances of the historical version of the semiconductor structure in the prior process state by a reference metrology system.

In general, the training data set may include historical measurement signals and corresponding values of one or more parameters of interest associated with the full structure of interest, any combination of the component structures, {C₁ . . . C_{N}}, or both.

In general, training data sets may include training data associated with historical, prior state measurements at any number of prior process steps. Each of the different prior states of the semiconductor process flow and the present state of the semiconductor process flow are separated by one or more intervening semiconductor manufacturing process steps. Furthermore, each of the different prior states of the semiconductor process flow and any other of the different prior states are separated by one or more intervening semiconductor manufacturing process steps.

In some examples, training data continues to be generated based on reliable, high-throughput, in-line measurements of a continuously growing number of instances of a structure of interest at a prior state, along with corresponding high-throughput, in-line measurement signals in the present state. In these examples, prior state and present state measurements continue to be collected from in-line, production wafers. Periodically, the expanded set of training data is employed to retrain the present state measurement model to continuously improve the accuracy and reliability of the trained present state measurement model as production continues.

In general, the training data set including the

training set of measurement signals 165 and corresponding values of one or more Design of Experiments (DOE) parameters of interest 166 includes any combination of real signals and synthetically generated signals at present and prior process states from current and historical measurement targets and component targets.

In a further aspect, values of one or more parameters of interest estimated by a machine learning based component measurement model from a set of measurement signals are employed as seed values in a regression based fitting of another measurement model to estimate refined values of the one or more parameters of interest.

As depicted in FIG. 1, metrology tool 100

includes a computing system 130 employed to acquire signals 135 generated by detector 119 and determine properties of a semiconductor structure based at least in part on the acquired signals in accordance with transmission based, scatterometry measurement techniques described herein. In the embodiment depicted in FIG. 1, computing system 130 is configured as a component based measurement engine configured to implement component measurement functionality as described herein.

However, in general, component measurement functionality as described herein may be implemented on any number of different metrology systems, including, but not limited to, various X-ray based measurement modalities, such as X-ray scatterometry, X-ray reflectometry, X-ray diffraction, X-ray fluorescence, etc., various optically based measurement modalities, such as spectroscopic reflectometry, scatterometry, and ellipsometry, image based reflectometry, etc., and various electron beam based measurement modalities, such as model based electron beam metrology.

In general, the scattering response signals or scattering response images described herein refer to pixel intensity values at the detector plane or diffraction order intensity values. Diffraction order intensity values are not directly measured by a transmission based, X-ray scatterometry system, but are derived from measured pixel intensities at the detector plane. However, synthetically generated diffraction order intensities may be computed directly. In some embodiments, it is desirable to compute and mathematically operate on diffraction order intensities to reduce computational effort.

Component model based measurements of semiconductor structures as described herein may be employed as part of a semiconductor fabrication process in a number of different ways. In some embodiments, measurement results are employed directly to control a fabrication process. In some examples, measured values of one or more parameters of interest, e.g., critical dimensions, are directly employed to control one or more process parameters, e.g., focus, dosage, etch time, etc.

In some embodiments, the structures under measurement include some amount of periodicity to scatter light in discernable discrete diffraction orders. Diffraction from structures exhibiting periodicity in two dimensions appears as discrete points on the image plane of the detector. Diffraction from structures exhibiting periodicity in one dimension appears as discrete points on a line in the image plane of the detector.

In some embodiments, the structures under measurement are quasi-periodic in one or both in-plane dimensions. In these embodiments, the diffraction images exhibit continuous lines of diffracted light.

In general, scatterometry based measurements as described herein may be employed to measure any semiconductor structure that exhibits periodicity or quasi-periodicity in one or both in-plane dimensions, e.g., the x-direction, the y-direction, or both.

Scatterometry based measurements, as described herein, may be performed using narrowband illumination light centered about any suitable illumination wavelength, e.g., narrowband illumination light centered about any wavelength suitable to transmit through the wafer and generate scattering from stacked structures. Although, in many measurement applications, the wavelength of illumination light is in the X-Ray range, in general, depending on the size of structures under measurement, the wavelength of illumination light may be in the optical range, including ultraviolet, visible, and infrared ranges. In preferred embodiments, the illumination light is narrow band with low beam divergence to reduce smearing of diffraction orders at the detector due to varying illumination wavelengths. Order separation on an X-Ray detector, specifically, is a function of wavelength, target periodicity, incidence angle, divergence angle of the uncollimated illumination light, detector resolution and distance from the target, etc. Nevertheless, in one dimension it is fundamentally governed by the diffraction equation, d*sin(Δθ)=λ, where d is the periodicity of the structure, λ is the illuminating wavelength and Δθ is the angular spacing between orders. From this equation or the two dimensional equivalent, a practitioner skilled in the art may quickly determine the bandwidth and beam divergence required to resolve the individual orders on a detector.

Although useful measurements may be performed at two different incidence angles, in general, measurement sensitivity is improved by collecting measurement data over a large, diverse data set. This is achieved by collecting measurement data over a longer period of time, over a larger range of different illumination incidence angles, over a smaller spacing between different illumination incidence angles, or any combination thereof.

It should be recognized that the various steps described throughout the present disclosure may be carried out by a single computer system 130 or, alternatively, a multiple computer system 130. Moreover, different subsystems of the system 100, such as the specimen positioning system 140, may include a computer system suitable for carrying out at least a portion of the steps described herein. Therefore, the aforementioned description should not be interpreted as a limitation on the present invention but merely an illustration. Further, the one or more computing systems 130 may be configured to perform any other step(s) of any of the method embodiments described herein.

In addition, the computer system 130 may be communicatively coupled to the x-ray illumination source 110, beam shaping slit mechanism 120, specimen positioning system 140, and detector 119 in any manner known in the art. For example, the one or more computing systems 130 may be coupled to computing systems associated with the x-ray illumination source 110, beam shaping slit mechanism 120, specimen positioning system 140, and detector 119, respectively. In another example, any of the x-ray illumination source 110, beam shaping slit mechanism 120, specimen positioning system 140, and detector 119 may be controlled directly by a single computer system coupled to computer system 130.

The computer system 130 may be configured to receive and/or acquire data or information from the subsystems of the system (e.g., x-ray illumination source 110, beam shaping slit mechanism 120, specimen positioning system 140, detector 119, and the like) by a transmission medium that may include wireline and/or wireless portions. In this manner, the transmission medium may serve as a data link between the computer system 130 and other subsystems of the system 100.

Computer system 130 of the metrology system 100 may be configured to receive and/or acquire data or information (e.g., measurement results, modeling inputs, modeling results, etc.) from other systems by a transmission medium that may include wireline and/or wireless portions. In this manner, the transmission medium may serve as a data link between the computer system 130 and other systems (e.g., memory on-board metrology system 100, external memory, or external systems). For example, the computing system 130 may be configured to receive measurement data (e.g., signals 135) from a storage medium (i.e., memory 132) via a data link. For instance, image results obtained using detector 119 may be stored in a permanent or semi-permanent memory device (e.g., memory 132). In this regard, the measurement results may be imported from on-board memory or from an external memory system. Moreover, the computer system 130 may send data to other systems via a transmission medium.

Computing system 130 may include, but is not limited to, a personal computer system, mainframe computer system, cloud-based computing system, workstation, image computer, parallel processor, or any other device known in the art. In general, the term “computing system” may be broadly defined to encompass any device having one or more processors, which execute instructions from a memory medium.

Program instructions 134 implementing methods such as those described herein may be transmitted over a transmission medium such as a wire, cable, or wireless transmission link. For example, as illustrated in FIG. 1, program instructions stored in memory 132 are transmitted to processor 131 over bus 133. Program instructions 134 are stored in a computer readable medium (e.g., memory 132). Exemplary computer-readable media include read-only memory, a random access memory, a magnetic or optical disk, or a magnetic tape.

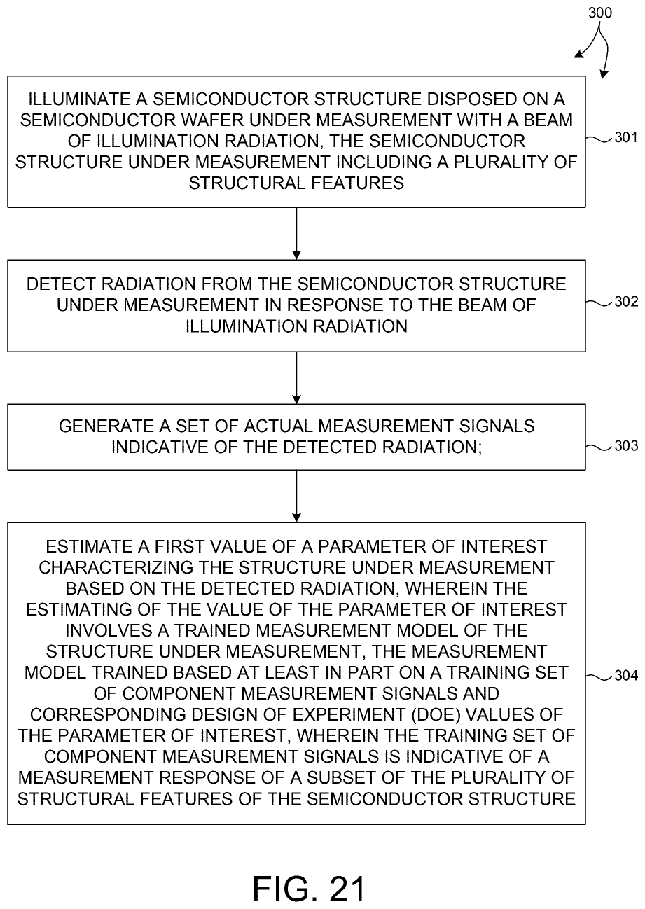

FIG. 21 illustrates a method 300 suitable for implementation by the metrology system 100 of the present invention. In one aspect, it is recognized that data processing blocks of method 300 may be carried out via a pre-programmed algorithm executed by one or more processors of computing system 130. While the following description is presented in the context of metrology system 100, it is recognized herein that the particular structural aspects of metrology system 100 do not represent limitations and should be interpreted as illustrative only.

In block 301, a semiconductor structure disposed on a semiconductor wafer under measurement is illuminated with a beam of illumination radiation. The semiconductor structure under measurement includes a plurality of structural features.

In block 302, radiation is detected from the semiconductor structure under measurement in response to the beam of illumination radiation.

In block 303, a set of actual measurement signals indicative of the detected radiation is generated.

In block 304, a first value of a parameter of interest characterizing the structure under measurement is estimated based on the detected radiation. The estimating of the value of the parameter of interest involves a trained measurement model of the structure under measurement. The measurement model is trained based at least in part on a training set of component measurement signals and corresponding Design Of Experiment (DOE) values of the parameter of interest. The training set of component measurement signals is indicative of a measurement response of a subset of the plurality of structural features of the semiconductor structure.

In some embodiments, component based measurements as described herein are implemented as part of a fabrication process tool. Examples of fabrication process tools include, but are not limited to, lithographic exposure tools, film deposition tools, implant tools, and etch tools. In this manner, the results of a component based analysis are used to control a fabrication process. In one example, T-SAXS measurement data collected from one or more targets is sent to a fabrication process tool. The T-SAXS measurement data is analyzed as described herein and the results used to monitor, and when necessary, adjust, the operation of the fabrication process tool.

Scatterometry measurements as described herein may be used to determine characteristics of a variety of semiconductor structures. Exemplary structures include, but are not limited to, FinFETs, low-dimensional structures such as nanowires or graphene, sub 10 nm structures, lithographic structures, through substrate vias (TSVs), memory structures such as DRAM, DRAM 4F2, FLASH, MRAM and high aspect ratio memory structures. Exemplary structural characteristics include, but are not limited to, geometric parameters such as line edge roughness, line width roughness, pore size, pore density, side wall angle, profile, critical dimension, pitch, thickness, overlay, and material parameters such as electron density, composition, grain structure, morphology, stress, strain, and elemental identification. In some embodiments, the metrology target is a periodic structure. In some other embodiments, the metrology target is aperiodic.

In some examples, measurements of critical dimensions, thicknesses, overlay, and material properties of stacked ratio semiconductor structures including, but not limited to, spin transfer torque random access memory (STT-RAM), three dimensional NAND memory (3D-NAND) or vertical NAND memory (V-NAND), dynamic random access memory (DRAM), three dimensional FLASH memory (3D-FLASH), resistive random access memory (Re-RAM), and phase change random access memory (PC-RAM) are performed with T-SAXS measurement systems as described herein.

As described herein, the term “critical dimension” includes any critical dimension of a structure (e.g., bottom critical dimension, middle critical dimension, top critical dimension, sidewall angle, grating height, etc.), a critical dimension between any two or more structures (e.g., distance between two structures), and a displacement between two or more structures (e.g., overlay displacement between overlaying grating structures, etc.). Structures may include three dimensional structures, patterned structures, overlay structures, etc.

As described herein, the term “critical dimension application” or “critical dimension measurement application” includes any critical dimension measurement.

As described herein, the term “metrology system” includes any system employed at least in part to characterize a specimen in any aspect, including critical dimension applications and overlay metrology applications. However, such terms of art do not limit the scope of the term “metrology system” as described herein. In addition, the metrology systems described herein may be configured for measurement of patterned wafers and/or unpatterned wafers. The metrology system may be configured as a LED inspection tool, edge inspection tool, backside inspection tool, macro-inspection tool, or multi-mode inspection tool (involving data from one or more platforms simultaneously), and any other metrology or inspection tool that benefits from the measurement techniques described herein.

Various embodiments are described herein for a semiconductor processing system (e.g., an inspection system or a lithography system) that may be used for processing a specimen. The term “specimen” is used herein to refer to a wafer, a reticle, or any other sample that may be processed (e.g., printed or inspected for defects) by means known in the art.

As used herein, the term “wafer” generally refers to substrates formed of a semiconductor or non-semiconductor material. Examples include, but are not limited to, monocrystalline silicon, gallium arsenide, and indium phosphide. Such substrates may be commonly found and/or processed in semiconductor fabrication facilities. In some cases, a wafer may include only the substrate (i.e., bare wafer). Alternatively, a wafer may include one or more layers of different materials formed upon a substrate. One or more layers formed on a wafer may be “patterned” or “unpatterned.” For example, a wafer may include a plurality of dies having repeatable pattern features.

A “reticle” may be a reticle at any stage of a reticle fabrication process, or a completed reticle that may or may not be released for use in a semiconductor fabrication facility. A reticle, or a “mask,” is generally defined as a substantially transparent substrate having substantially opaque regions formed thereon and configured in a pattern. The substrate may include, for example, a glass material such as amorphous SiO₂. A reticle may be disposed above a resist-covered wafer during an exposure step of a lithography process such that the pattern on the reticle may be transferred to the resist.

One or more layers formed on a wafer may be patterned or unpatterned. For example, a wafer may include a plurality of dies, each having repeatable pattern features. Formation and processing of such layers of material may ultimately result in completed devices. Many different types of devices may be formed on a wafer, and the term wafer as used herein is intended to encompass a wafer on which any type of device known in the art is being fabricated.

In one or more exemplary embodiments, the functions described may be implemented in hardware, software, firmware, or any combination thereof. If implemented in software, the functions may be stored on or transmitted over as one or more instructions or code on a computer-readable medium. Computer-readable media includes both computer storage media and communication media including any medium that facilitates transfer of a computer program from one place to another. A storage media may be any available media that can be accessed by a general purpose or special purpose computer. By way of example, and not limitation, such computer-readable media can comprise RAM, ROM, EEPROM, CD-ROM or other optical disk storage, magnetic disk storage or other magnetic storage devices, or any other medium that can be used to carry or store desired program code means in the form of instructions or data structures and that can be accessed by a general-purpose or special-purpose computer, or a general-purpose or special-purpose processor. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, includes compact disc (CD), laser disc, XRF disc, digital versatile disc (DVD), floppy disk and blu-ray disc where disks usually reproduce data magnetically, while discs reproduce data optically with lasers. Combinations of the above should also be included within the scope of computer-readable media.

Although certain specific embodiments are described above for instructional purposes, the teachings of this patent document have general applicability and are not limited to the specific embodiments described above. Accordingly, various modifications, adaptations, and combinations of various features of the described embodiments can be practiced without departing from the scope of the invention as set forth in the claims.

What is claimed is:

1. A metrology system comprising:
an illumination source configured to generate a beam of radiation incident on a semiconductor structure disposed on a semiconductor wafer under measurement, the semiconductor structure under measurement including a plurality of structural features;
a detector configured to detect radiation from the semiconductor structure under measurement in response to the incident beam of radiation and generate a set of actual measurement signals indicative of the detected radiation; and
a computing system configured to:
estimate a first value of a parameter of interest characterizing the structure under measurement based on the detected radiation, wherein the estimating of the value of the parameter of interest involves a trained measurement model of the structure under measurement, the measurement model trained based at least in part on a training set of component measurement signals and corresponding Design Of Experiment (DOE) values of the parameter of interest, wherein the training set of component measurement signals is indicative of a measurement response of a subset of the plurality of structural features of the semiconductor structure to measurement by the metrology system.

2. The metrology system of claim 1, wherein the estimating of the value of the parameter of interest involves:
extracting a set of component measurement signals from the set of actual measurement signals; and
fitting the trained measurement model to the set of component measurement signals.

3. The metrology system of claim 1, wherein the training set of component measurement signals includes component measurement signals extracted from a training set of measurement signals indicative of a measured response of the plurality of structural features of the semiconductor structure to measurement by the metrology system.

4. The metrology system of claim 1, wherein the training set of component measurement signals includes synthetic component measurement signals generated by a component measurement model evaluated at a range of values of the parameter of interest and a range of values of one or more measurement system parameters.

5. The metrology system of claim 1, wherein the training set of component measurement signals includes component measurement signals generated by a measurement of the semiconductor structure at a prior process state, wherein the subset of the plurality of structural features of the semiconductor structure are present at the prior process state.

6. The metrology system of claim 1, the measurement model also trained based at least in part on a training set of measurement signals and corresponding Design Of Experiment (DOE) values of the parameter of interest, wherein the training set of measurement signals are indicative of a measurement response of the plurality of structural features of the semiconductor structure to measurement by the metrology system.

7. The metrology system of claim 1, the measurement model also trained based at least in part on a training set of historical component measurement signals, wherein the historical component measurement signals are indicative of a measurement response of a historical version of the subset of the plurality of structural features of the semiconductor structure to measurement by the metrology system.

8. The metrology system of claim 7, wherein the historical version of the subset of the plurality of structural features of the semiconductor structure differs from the subset of the plurality of structural features of the semiconductor structure in a design revision, a process recipe, or both.

9. The metrology system of claim 1, wherein the trained measurement model is a machine learning based measurement model or a library based measurement model.

10. The metrology system of claim 1, the computing system further configured to:
estimate a second value of the parameter of interest characterizing the structure under measurement, wherein the estimating of the second value of the parameter of interest involves fitting a second measurement model to the set of actual measurement signals, wherein the first value of the parameter of interest is employed as a seed value in the fitting of the second measurement model to the set of actual measurement signals.

11. The metrology system of claim 1, wherein the amount of radiation includes electron radiation, electromagnetic radiation in an x-ray range, electromagnetic radiation in an optical range, or any combination thereof.

12. A method comprising:
illuminating a semiconductor structure disposed on a semiconductor wafer under measurement with a beam of illumination radiation, the semiconductor structure under measurement including a plurality of structural features;
detecting radiation from the semiconductor structure under measurement in response to the beam of illumination radiation;
generate a set of actual measurement signals indicative of the detected radiation; and
estimate a first value of a parameter of interest characterizing the structure under measurement based on the detected radiation, wherein the estimating of the value of the parameter of interest involves a trained measurement model of the structure under measurement, the measurement model trained based at least in part on a training set of component measurement signals and corresponding Design Of Experiment (DOE) values of the parameter of interest, wherein the training set of component measurement signals is indicative of a measurement response of a subset of the plurality of structural features of the semiconductor structure.

13. The method of claim 12, wherein the estimating of the value of the parameter of interest involves:
extracting a set of component measurement signals from the set of actual measurement signals; and
fitting the trained measurement model to the set of component measurement signals.

14. The method of claim 12, further comprising:
generating synthetic component measurement signals at a range of values of the parameter of interest and a range of values of one or more measurement system parameters of a component measurement model, wherein the training set of component measurement signals includes the synthetic component measurement signals.

15. The method of claim 12, further comprising:
generating prior state component measurement signals by a measurement of the semiconductor structure at a prior process state, wherein the training set of component measurement signals includes the prior state component measurement signals, and wherein the subset of the plurality of structural features of the semiconductor structure are present at the prior process state.

16. The method of claim 12, further comprising:
training the measurement model based at least in part on a training set of historical component measurement signals, wherein the historical component measurement signals are indicative of a measurement response of a historical version of the subset of the plurality of structural features of the semiconductor structure to measurement.

17. The method of claim 12, wherein the trained measurement model is a machine learning based measurement model or a library based measurement model.

18. The method of claim 12, further comprising:
estimating a second value of the parameter of interest characterizing the structure under measurement, wherein the estimating of the second value of the parameter of interest involves fitting a second measurement model to the set of actual measurement signals, wherein the first value of the parameter of interest is employed as a seed value in the fitting of the second measurement model to the set of actual measurement signals.

19. The method of claim 12, wherein the amount of radiation includes electron radiation, electromagnetic radiation in an x-ray range, electromagnetic radiation in an optical range, or any combination thereof.

20. A metrology system comprising:
an illumination source configured to generate a beam of radiation incident on a semiconductor structure disposed on a semiconductor wafer under measurement, the semiconductor structure under measurement including a plurality of structural features;
a detector configured to detect radiation from the semiconductor structure under measurement in response to the incident beam of radiation and generate a set of actual measurement signals indicative of the detected radiation; and
a non-transitory, computer-readable medium storing instructions that, when executed by one or more processors, causes the one or more processors to:
estimate a first value of a parameter of interest characterizing the structure under measurement based on the detected radiation, wherein the estimating of the value of the parameter of interest involves a trained measurement model of the structure under measurement, the measurement model trained based at least in part on a training set of component measurement signals and corresponding Design Of Experiment (DOE) values of the parameter of interest, wherein the training set of component measurement signals is indicative of a measurement response of a subset of the plurality of structural features of the semiconductor structure to measurement by the metrology system.
